(19) United States
(12) Patent Application Publication
(10) Pub. No.: US 2006/0028854 A1
(43) Pub. Date: Feb. 9, 2006

(54) Charge pump circuit

(75) Inventor: Shuhei Kawai, Ora-gun (JP)

Correspondence Address: MORRISON & FOERSTER LLP, 1650 TYSONS BOULEVARD, SUITE 300, MCLEAN, VA, 22102, US

(73) Assignee: SANYO ELECTRIC CO., LTD., Osaka (JP)

(21) Appl. No.: 11/192,402

(22) Filed: Jul. 29, 2005

(30) Foreign Application Priority Data
Aug. 4, 2004 (JP) 2004-228004

(51) Int. Cl. G11C 17/00

(52) U.S. Cl. 365/96

(57) ABSTRACT

Stable control of an output voltage of a charge pump circuit is made possible by feed-back control using Pulse Width Modulation. The charge pump circuit of this invention includes a first and a second charge transfer MOS transistors connected in series, a capacitor with a first terminal connected to a connecting node between the first charge transfer MOS transistor and the second charge transfer MOS transistor, an integration circuit that generates a ramp voltage that corresponds to clocks, a comparator that compares the ramp voltage with a voltage corresponding to an output voltage from the second charge transfer MOS transistor, a divider that divides a frequency of the clocks in half and a NAND circuit that masks an output of the comparator according to an output of the divider. An output of the NAND circuit is applied to a second terminal of the capacitor.

### CROSS-REFERENCE OF THE INVENTION

This invention is based on Japanese Patent Application No. 2004-228004, the content of which is incorporated herein by reference in its entirety.

### BACKGROUND OF THE INVENTION

1. Field of the Invention

This invention relates to a charge pump circuit, specifically to a charge pump circuit having an output voltage regulation function.

2. Description of the Related Art

A charge pump circuit is composed of a charge transfer device, a capacitor, a clock driver and other components. It steps up an input voltage and outputs the boosted voltage, and is widely used as a power supply circuit for a transistor circuit and the like. In order to stabilize the output voltage of the charge pump circuit, an operational amplifier has been used as a series regulator to regulate the output voltage to a prescribed constant voltage. The charge pump circuit using the regulator is disclosed in Japanese Patent Application Publication No. 2001-231249, for example.

However, the conventional regulator is not stable enough when a high output voltage of the charge pump circuit is undesirable, when a smoothing capacitor connected to the output of the charge pump circuit preceding the regulator is eliminated, or when the output voltage is supplied as a power supply voltage to a transistor to drive it optimally. Thus, a feed-back control is required to enhance stability of the output voltage.

### SUMMARY OF THE INVENTION

A charge pump circuit includes a plurality of charge transfer devices connected in series, a capacitor with a first terminal connected to a connecting node between the charge transfer devices, a ramp voltage generation circuit that generates a ramp voltage corresponding to clocks, a comparator that compares the ramp voltage with a voltage corresponding to an output voltage from the charge transfer device, a divider that divides a frequency of the clocks and a masking circuit that masks an output of the comparator according to an output of the divider. A signal corresponding to the output of the masking circuit is applied to a second terminal of the capacitor.

### BRIEF DESCRIPTION OF THE DRAWINGS

FIG. 1 is a circuit diagram showing a charge pump circuit according to an embodiment of this invention.

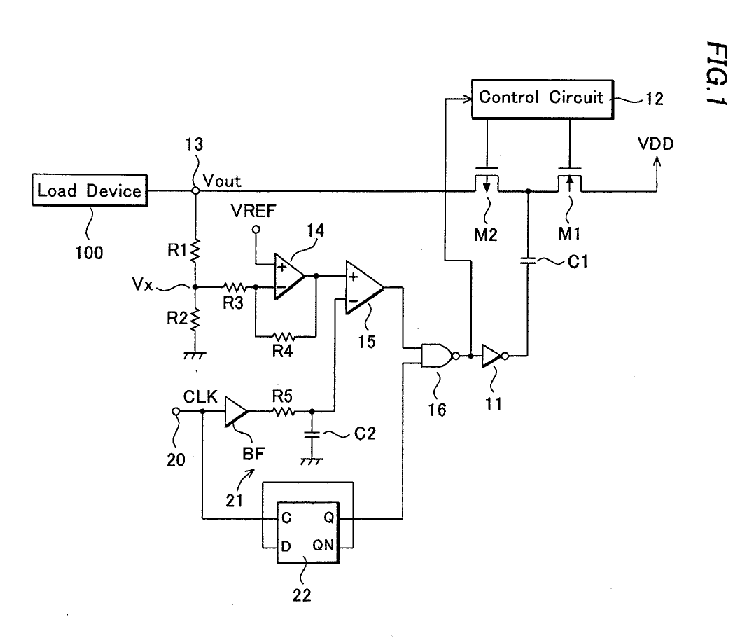

FIG. 2 is a wave form chart showing operational wave forms in the charge pump circuit according to the embodiment of this invention.

### DETAILED DESCRIPTION OF THE INVENTION

Next, an embodiment of this invention will be explained hereinafter referring to the figures. A first charge transfer MOS transistor M1 and a second charge transfer MOS transistor M2 are connected in series. A power supply voltage VDD is supplied to a source of the first charge transfer MOS transistor M1 as an input voltage.

While the first charge transfer MOS transistor M1 may be either N-channel type or P-channel type, the second charge transfer MOS transistor M2 is preferably P-channel type. The reason is that a high voltage to turn on the second charge transfer MOS transistor M2 is not available in this circuit, if the second charge transfer MOS transistor M2 is N-channel type.

A first terminal of a capacitor C1 is connected to a connecting node between the first charge transfer MOS transistor M1 and the second charge transfer MOS transistor M2. A clock driver 11 provides a second terminal of the capacitor C1 with clocks. The clock driver 11 is an inverter to which the power supply voltage VDD is supplied. A control circuit 12 provides each gate of the first and second charge transfer MOS transistors M1 and M2 with each of first and second control signals, respectively, to turn the transistors on and off. The control circuit 12 generates the first and second signals based on an output signal of a NAND circuit 16.

A drain of the second charge transfer MOS transistor M2 is connected to an output terminal 13, from which an output voltage Vout is obtained. The output voltage Vout is supplied to a load device 100 that is connected to the output terminal 13. Resistors R1 and R2 for dividing the output voltage Vout are connected in series with each other and connected between the output terminal 13 and the ground. A divided voltage Vx generated at a connecting node between R1 and R2 is inputted to a negative input terminal (−) of an error amplifier 14 through a resistor R3. A reference voltage VREF is inputted to a positive input terminal (+) of the error amplifier 14. And a feed-back resistor R4 is connected between an output terminal and the negative input terminal (−) of the error amplifier 14. Assuming R3 and R4 represent resistance of the resistors R3 and R4, respectively, R3 is set to be much smaller than R4 (R3<<R4). Then an output voltage of the error amplifier 14 is approximately expressed by the following equation:
Vo=VREF+(R4/R3)×(VREF−Vx) (1)

Based on this equation (1), the error amplifier 14 multiplies an error between the divided voltage Vx and the reference voltage VREF by (R4/R3). The output voltage Vo of the error amplifier 14 is inputted to a positive input terminal (+) of a comparator 15.

Clocks CLK inputted from a clock input terminal 20 go through an integration circuit 21 to be converted into a ramp voltage (triangle wave). The integration circuit 21 is composed of a buffer BF, a resistor R5 and a capacitor C2. The ramp voltage from the integration circuit 21 is inputted to a negative input terminal (−) of the comparator 15.

An output of the comparator 15 is inputted to an input terminal of the NAND circuit 16 that serves as a masking circuit. A frequency of the clocks CLK is divided in half through a divider 22 that uses a flip-flop. An output of the divider 22 is inputted to another input terminal of the NAND circuit 16. The output of the NAND circuit 16 is supplied to the clock driver 11 and the control circuit 12.

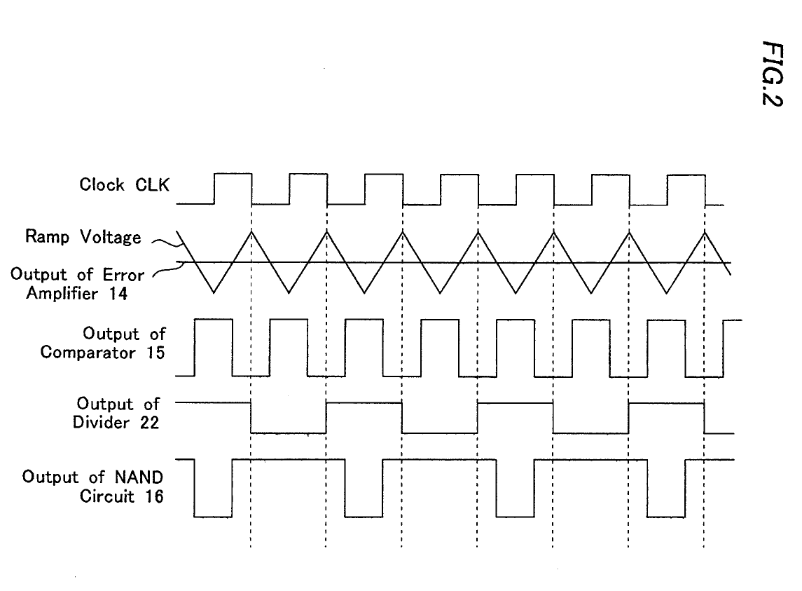

Next, operation of the charge pump circuit described above will be explained referring to wave forms shown in FIG. 2. By comparing the ramp voltage (triangle wave) from the integration circuit 21 and the output voltage Vo of the error amplifier 14 using the comparator 15, a PWM (Pulse Width Modulation) output having a duty ranging from 0 to 100% depending on a level of the output Vo of the error amplifier 14 is obtained from the comparator 15. That is, the PWM output is at a high level when the output voltage Vo of the error amplifier 14 is higher than the ramp voltage, and the PWM output is at a low level when the output voltage Vo of the error amplifier 14 is lower than the ramp voltage. Boosting capability of the charge pump circuit is maximized when a duty of the clock outputted from the clock driver 11 is 50%, that is, when a low period and a high period of the clock have the same duration. That is because a balance between charging and discharging is lost and full use of the capability of the charge pump is not made in each of the periods when the low period and the high period of the clock are not the same.

Controlling the duty of the PWM output within a range from 50 to 100% is made possible in this embodiment by masking the PWM output of the comparator 15 for a period during which the output of the divider 22 is at a low level using the NAND circuit 16 to which the PWM output of the comparator 15 and the output of the divider 22 are inputted. It is also possible to control the duty of the PWM output within a range from 0 to 50% in a similar way.

The boosting operation of the charge pump circuit is described below. When the output of the clock driver 11 is a low level, the control circuit 12 turns the first charge transfer MOS transistor M1 on and the second charge transfer MOS transistor M2 off to charge the capacitor C1 through the first charge transfer MOS transistor M1.

Next, when the output of the clock driver 11 turns to a high level, the control circuit 12 turns the first charge transfer MOS transistor M1 off and the second charge transfer MOS transistor M2 on to discharge electric charges stored in the capacitor C1 to the output terminal 13 through the second charge transfer MOS transistor M2. As a result, the output voltage Vout is boosted. The operation reaches a stable state when the charging and discharging operations and a capacity of the load device 100 are balanced.

In the stable state, the output voltage Vout is set to a voltage approximately expressed by the following equation (2):
Vout=VREF×(R1+R2)/R2 (2)
where R1 and R2 represent resistance of the resistors R1 and R2.

In some cases, the output voltage Vout is reduced from a predetermined voltage by expected and unexpected some reasons. Consequently, the divided voltage Vx is also reduced, and the output voltage Vo of the error amplifier 14 is increased according to the equation (1). Since the duty of the PWM output of the NAND circuit 16 gets closer to 50% as a result, the boosting capability of the charge pump circuit is enhanced to increase the output voltage Vout. In other cases, the output voltage Vout is increased from the predetermined voltage by other reasons. Consequently, the divided voltage Vx is also increased, and the output voltage Vo of the error amplifier 14 is reduced according to the equation (1). Since the duty of the PWM output of the NAND circuit 16 is reduced farther away from 50% as a result, the boosting capability of the charge pump circuit is reduced to decrease the output voltage Vout.

According to the embodiment, as described above, the output voltage Vout of the charge pump circuit can be controlled extremely stable by controlling the boosting capability of the charge pump circuit through the feed-back control using the PWM. Although a two-stage charge pump circuit that has the maximum boosting capability of 2VDD is described as an example in the embodiment, the number of stages may be increased to three or more. Or, this embodiment may be applicable to any charge pump circuit including a ½ VDD boosting charge pump circuit and a minus voltage boosting charge pump circuit, for example, as long as the charge pump circuit includes a combination of a charge transfer device and a capacitor.

According to this invention, stable control of the output voltage of the charge pump circuit is made possible by the feed-back control using the PWM.

What is claimed is:

1. A charge pump circuit comprising:
a first charge transfer device and a second charge transfer device that are connected in series;
a capacitor;
a ramp voltage generation circuit that generates a ramp voltage corresponding to a clock;
a comparator that compares the ramp voltage with a voltage corresponding to an output voltage from the first and second charge transfer devices;
a divider that divides a frequency of the clock; and
a masking circuit that masks an output of the comparator according to an output of the divider,
wherein a first terminal of the capacitor is connected with a connecting node between the first and second charge transfer devices, and a second terminal of the capacitor is configured to receive a signal corresponding to an output of the masking circuit.

2. The charge pump circuit of claim 1, further comprising a control circuit that controls turning on and off of the first and second charge transfer devices according to the output of the masking circuit.

3. The charge pump circuit of claim 1, wherein the ramp voltage generation circuit comprises an integration circuit comprising a resistor and a capacitor, the integration circuit being provided with the clock as an input.

4. The charge pump circuit of claim 1, further comprising two or more resistor that generate a divided voltage of the output voltage from the first and second charge transfer devices and an amplifier that amplifies an error between a voltage corresponding to the divided voltage and a reference voltage, wherein the comparator compares the ramp voltage with an output voltage of the amplifier.

5. The charge pump circuit of claim 1, wherein the divider divides the frequency of the clock in half.

6. The charge pump circuit of claim 1, wherein the masking circuit comprises a NAND circuit.

7. The charge pump circuit of claim 1, further comprising a clock driver, wherein the output of the masking circuit is applied to the second terminal of the capacitor through the clock driver.
